(19) United States
(12) Patent Application Publication
(10) Pub. No.: US 2025/0014892 A1
(43) Pub. Date: Jan. 9, 2025

(54) LOW-PRESSURE OXIDATION TREATMENT METHOD AND DEVICE FOR SEMICONDUCTOR WORKPIECES

(71) Applicant: Beijing E-Town Semiconductor Technology Co., Ltd., Beijing (CN)

(72) Inventors: Jianmin JI, Beijing (CN); Manshi YAO, Beijing (CN); Haiwei LI, Beijing (CN)

(21) Appl. No.: 18/744,978

(22) Filed: Jun. 17, 2024

(30) Foreign Application Priority Data
Jul. 6, 2023 (CN) 202310826140.3

(51) Int. Cl. H01L 21/02; H01J 37/32

(52) U.S. Cl. CPC H01L 21/02238; H01L 21/02164; H01L 21/02252; H01J 37/3244; H01J 37/32834; H01J 2237/186; H01J 2237/338

(57) ABSTRACT

Provided is a low-pressure oxidation treatment method and device for a semiconductor workpiece. The low-pressure oxidation treatment method includes: pumping a reaction chamber such that the reaction chamber has a pressure lower than 760 Torr; introducing a process gas including hydrogen and oxygen to the reaction chamber; increasing a temperature within the reaction chamber to cause the process gas to generate oxygen radicals; and exposing the semiconductor workpiece to the oxygen radicals to form an oxide film on a surface of the semiconductor workpiece.

### CROSS-REFERENCE TO RELATED APPLICATIONS

The present application claims priority to Chinese Patent Application No. CN202310826140.3, filed with the China National Intellectual Property Administration on Jul. 6, 2023, the disclosure of which is hereby incorporated herein by reference in its entirety.

### TECHNICAL FIELD

The disclosure relates to the field of semiconductor manufacturing, and especially, to a low-pressure oxidation method and device for semiconductor workpieces, and more particularly, to a low-pressure oxygen radical oxidation method and device.

### BACKGROUND

The oxidation method of semiconductor workpieces, in particular silicon wafers, is generally carried out by thermal treatment in an atmosphere of O₂, H₂O/H₂, H₂O/O₂, O₂/I₂. Conventional thermal treatment processes may include hot-melt furnaces and rapid thermal treatment, among which oxidation systems typically require temperatures above 700° C. to provide activation energy for oxide growth on the surface of silicon wafers, and temperatures below 700° C. may result in insufficient oxidation.

### SUMMARY

The disclosure provides a low-pressure oxidation treatment method and a low-pressure oxidation treatment device for a semiconductor workpiece.

According to an aspect of the disclosure, there is provided a low-pressure oxidation treatment method for a semiconductor workpiece, including:
pumping a reaction chamber such that the reaction chamber has a pressure lower than 760 Torr;
introducing a process gas including hydrogen and oxygen to the reaction chamber;
increasing a temperature within the reaction chamber to cause the process gas to generate oxygen radicals; and
exposing the semiconductor workpiece to the oxygen radicals to form an oxide film on a surface of the semiconductor workpiece.

According to another aspect of the disclosure, there is provided a low-pressure oxidation treatment device for a semiconductor workpiece, including a reaction chamber, at least one heating element, and a vacuum generating system.

According to the low-pressure oxidation treatment method, the oxygen radicals are utilized to promote the growth of the oxide film, thereby improving the uniformity of the oxide film and reducing the defects of the oxide film.

It should be understood that the content described herein is not intended to identify critical or essential features of embodiments of the present disclosure, nor is it used to limit the scope of the present disclosure. Other features of the present disclosure will be easily understood through the following description.

### BRIEF DESCRIPTION OF THE DRAWINGS

The accompanying drawings are included to provide a better understanding of the present solution and are not to be considered as limiting the disclosure, in which:

FIG. 1 is a plan view of a low-pressure oxidation treatment device according to an embodiment of the present disclosure;

FIG. 2 is a right-side view of the low-pressure oxidation treatment device according to the embodiment of the present disclosure; and

FIGS. 3 and 4 are schematic views illustrating processes of oxidating a silicon wafer with oxygen and oxygen radicals, respectively.

### DETAILED DESCRIPTION

Exemplary embodiments of the disclosure will be described below with reference to the accompanying drawings, in which various details of embodiments of the disclosure are included to assist understanding, and which are to be considered as merely exemplary. Accordingly, it will be recognized by those having ordinary skill in the art that various changes and modifications may be made to the embodiments described herein without departing from the scope of the disclosure. Also, descriptions of well-known functions and constructions are omitted in the following description for clarity and conciseness.

Currently, semiconductor workpieces (e.g., silicon wafers) are typically formed by a remote plasma oxidation process, such as a microwave plasma source that generates an oxygen radical rich plasma that reacts with silicon on a surface of the silicon wafer in an atmospheric pressure and high temperature reaction chamber to form an oxide film of silicon oxide on the surface of the silicon wafer. In the atmospheric pressure and high temperature process, the control accuracy of temperature is particularly important for the remote plasma oxidation process.

### Low-Pressure Oxidation Treatment Device

A low-pressure oxidation treatment device according to an embodiment of the present disclosure may include a workpiece support element, a reaction chamber, at least one gas supply source, at least one heating element, and a vacuum generating system.

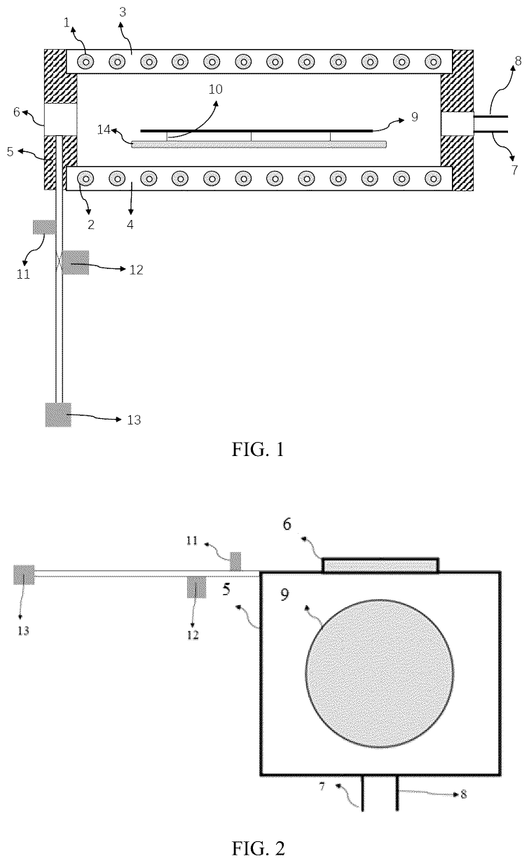

In particular, with reference to FIGS. 1 and 2, the low-pressure oxidation treatment device according to the embodiment includes an upper lamp panel 3, a lower lamp panel 4, a reaction chamber defined by the upper lamp panel 3, the lower lamp panel 4 and a reaction chamber body 5, an upper lamp group 1 inside the upper lamp panel 3, a lower lamp group 2 inside the lower lamp panel 4, a wafer inlet/outlet 6 on a side wall at an end of the reaction chamber, and at least two gas inlets at an end of the reaction chamber opposite to the wafer inlet/outlet 6 for communicating with different gas sources.

According to an embodiment, the workpiece support element inside the reaction chamber may be configured to support a semiconductor workpiece to be processed, may have any shape, configuration and/or construction suitable for supporting the semiconductor workpiece, and may include a rotating disk (e.g., a quartz disk) 14 and a plurality of liftable support columns (e.g., quartz columns) 10 on the rotating disk 14 for supporting and rotating the workpiece to be processed (i.e., a silicon wafer 9).

According to an embodiment, the heating element includes two lamp groups which are arranged inside the upper and the lower lamp panels, respectively, to heat the semiconductor workpiece placed in the reaction chamber on its sides, so that a deformation of the wafer in the heating process can be reduced, a yield of the wafer can be effectively improved, higher power can be provided to increase a heating rate, and an output capacity in unit time can be improved. The lamp panel can be a quartz plate.

The lamp group may include a lamp array disposed in at least one region of the lamp panel. The lamp that can be used in the disclosure may be a halogen lamp. The upper lamp group heats an upper surface of the wafer supported by the workpiece support element between the upper lamp panel and the lower lamp panel, and the lower lamp group heats a lower surface of the wafer. Therefore, the upper lamp group and the lower lamp group can carry out double-sided radiation heating on the wafer, so that a graphic effect is effectively avoided and a stress on the wafer is improved.

According to an embodiment, the gas inlets may be provided on a side wall at an end of the reaction chamber body, or may be disposed on a ceiling of the reaction chamber body, or may be disposed on a side wall at an end and a ceiling of the reaction chamber body, so that it is possible to advantageously adjust an input amount of the gas according to an actual process and to form a uniform gas flow in the reaction chamber.

According to an embodiment, the at least two gas inlets at an end of the reaction chamber may be in communication with different gas sources, respectively, via gas conduits 7 and 8, for example in communication with a hydrogen source and an oxygen source for the process gas, respectively. According to another embodiment, the gas conduits may also be in communication with a nitrogen source. Furthermore, flow sensors (e.g., flow meters) and/or gas pressure control valves may also be provided to the gas conduits 7 and 8. The gas flow input into the reaction chamber is accurately measured through the flow sensor and the gas pressure control valve, so that it is advantageous to accurately adjust the pressure in the reaction chamber to be a low pressure.

According to an embodiment, the vacuum generating system is provided at and in communication with a lower part of the reaction chamber body at an end opposite to the gas inlets, and includes a vacuum pump 13, a sensor 11 and a control valve 12 in communication through a conduit. The sensor 11 and the control valve 12 are connected in communication with a controller of the low-pressure oxidation treatment device. Specifically, the vacuum pump 13 is activated to pump gas from the reaction chamber to control the amount of gas in the reaction chamber, thereby maintaining the pressure in the reaction chamber within a set range. The sensor 11 senses the pressure in the sensing chamber, feeds the sensed pressure value back to the controller (not shown) of the low-pressure oxidation treatment device, compares the measured pressure value with a preset value, and adjusts an opening of the control valve 12 according to a comparison result, that is, when the measured pressure value of the reaction chamber is more than the preset value, the opening of the control valve 12 is turned up to increase the amount of the gas to be pumped, thereby lowering the pressure in the reaction chamber; when the measured pressure value of the reaction chamber is less than the preset value, the opening of the control valve 12 is turned down to reduce the amount of gas to be pumped, thereby reducing the pressure in the reaction chamber.

According to an embodiment, the pressure in the reaction chamber is required to be, for example, lower than 760 Torr. Specifically, the low pressure is 1-20 Torr, preferably 2-15 Torr, and may be, for example, 3 Torr, 4 Torr, 6 Torr, 8 Torr, 10 Torr and 12 Torr. In the disclosure, a control accuracy of the pressure is within 0.1 Torr.

According to an embodiment, the low-pressure oxidation treatment device can achieve a thickness of 15-130 angstroms, such as 50 angstroms, 70 angstroms, 90 angstroms, 105 angstroms, 120 angstroms.

The low-pressure oxidation treatment device can perform high-quality oxidation on the surface of the silicon wafer under low-pressure (preferably, a pressure of 1-20 Torr), and the formed silicon oxide thin film has high uniformity, few defects and deep oxidation extent.

### Low-Pressure Oxidation Treatment Method

According to an aspect of the disclosure, there is provided a low-pressure oxidation treatment method for a semiconductor workpiece, comprising:
pumping a reaction chamber such that the reaction chamber has a pressure lower than 760 Torr;
introducing a process gas including hydrogen and oxygen to the reaction chamber;
increasing a temperature within the reaction chamber to cause the process gas to generate oxygen radicals; and
exposing the semiconductor workpiece to the oxygen radicals to form an oxide film on a surface of the semiconductor workpiece.

According to an embodiment, the low-pressure oxidation treatment method of the disclosure is performed at a low pressure lower than 760 Torr, specifically 1-20 Torr, preferably 2-15 Torr, for example, 3 Torr, 4 Torr, 6 Torr, 8 Torr, 10 Torr and 12 Torr.

According to an embodiment, the generation of the oxygen radicals from the process gas may occur at a temperature of 750-1100° C., preferably 800-1000° C., more preferably 850-950° C., such as 880° C. or 900° C.

According to an embodiment, the process gas used in the low-pressure oxidation treatment method described above includes hydrogen and oxygen, and preferably consists of the hydrogen and oxygen. Also, a total flow rate of the process gas may be 20-60 L/min, preferably 25-55 L/min, and more preferably 30-50 L/min, such as 35 L/min, 40 L/min, 45 L/min and 48 L/min. An excessively high total flow rate may affect a uniformity of a resulting oxide film, whereas an excessively low flow rate may lead to unstable pressure control, which may cause defects or non-uniform thickness of the resulting oxide film. Specifically, a flow percentage of hydrogen is more than 0 and less than or equal to 33%, preferably 1-28%, and more preferably 5-25%, such as 8%, 12%, 15%, 18%, 20% and 23%, based on the total flow rate of the process gas; a flow percentage of the oxygen is 67% or more and not 100%, preferably 70-95%, and more preferably 75-90%, such as 80% or 85%.

In the low-pressure oxidation treatment method of the disclosure, the process gas contains the hydrogen and the oxygen, so that the oxygen undergoes cleavage to generate oxygen radicals under the above-mentioned low pressure and high temperature conditions. The existence of hydrogen is helpful to prolong survival time of the oxygen radicals and accelerate oxidation rate, so that an oxidation treatment rate is increased and the formed oxide layer has a large thickness and a high growth rate, but it is not easy to control the uniformity of the oxide layer. Therefore, it is required to complete the oxidation treatment at an appropriate hydrogen flow rate and process time.

Further, for the purpose of process safety, the hydrogen is necessarily supplied only when the pressure in the reaction chamber is below 20 Torr. The process gas may be supplied from the side surface, the top surface, or both the side and top surfaces of the reaction chamber to provide a uniform gas flow across a wafer surface.

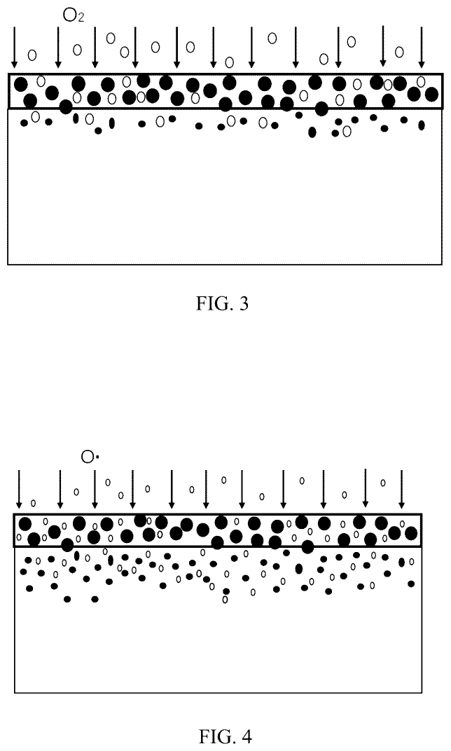

The low-pressure oxidation treatment method includes the step of generating oxygen radicals at a high temperature by using process gases of hydrogen and oxygen under the low-pressure condition so as to oxidize silicon on a surface of a wafer to form a silicon oxide layer. Specifically, reference can be made to FIG. 3 which is a schematic view illustrating a process of oxidizing a silicon wafer with oxygen in a conventional method, in which the oxygen first reacts with silicon on a surface of a silicon wafer to generate silicon oxide at a high temperature, and to gradually form a silicon oxide layer; when it is necessary to form the oxide layer further to the deep, oxygen molecules first need to pass through the generated silicon oxide layer. Due to a barrier of the generated silicon oxide molecules, a speed of penetration of the oxygen molecules to the deep silicon becomes slow, whereby an oxidation rate becomes slow and uniformity of the oxide layer is limited.

FIG. 4 is a schematic view illustrating an oxidation process of the low-pressure oxidation treatment method according to the disclosure. Herein, the oxygen undergoes cleavage to generate oxygen radicals under the conditions of low pressure and high temperature. As comparison, the diameter of an oxygen molecule is about 0.346 nm and the diameter of an oxygen radical is about 0.148 nm, i.e., the oxygen radical has a significantly smaller diameter than the oxygen molecule. Therefore, the oxygen radicals first react with silicon on the surface of the silicon wafer in the presence of the hydrogen to form silicon oxide, and to gradually form a silicon oxide layer; when it is necessary to form the oxide layer further to the deep, the oxygen radicals also need to penetrate through the formed silicon oxide layer. Due to the smaller diameter of oxygen radicals, although generated silicon oxide particles still pose some obstruction, these radicals diffuse more readily into the silicon layer within the wafer and penetrate to a deeper layer of the silicon at a significantly faster rate, thereby more favorably promoting the growth of the oxide film. Therefore, the oxidation treatment method according to the disclosure can improve the oxidation rate, and the oxide layer has higher uniformity, less defects and higher film quality.

The low pressure within the reaction chamber required by the low-pressure oxidation treatment method according to the disclosure needs to be achieved by a pressure control system. According to an embodiment, as shown in FIGS. 1 and 2, the pressure control system may include a gas source in communication with a gas inlet, and a vacuum generating system. A flow rate of gas, such as process gas, introduced into the reaction chamber is controlled. In the present disclosure, a total flow rate of the process gas is controlled to be 20-60 L/min and is kept constant. The flow rate of the introduced gas can be controlled by providing a flow sensor (e.g., a flow meter) and/or a gas pressure control valve on the gas conduits 7 and 8. In order to maintain the low pressure in the reaction chamber, a vacuum generating system including a vacuum pump 13, a sensor 11 and a control valve 12 is provided at an end opposite to the gas inlet, and the vacuum pump 13 is activated to pump gas from the reaction chamber while keeping the flow rate of the introduced gas substantially constant, so as to control the amount of gas in the reaction chamber, thereby maintaining the pressure in the reaction chamber within a set range. Further, the sensor 11 senses the pressure in the sensing chamber, feeds the sensed pressure value back to a controller (not shown) of the low-pressure oxidation treatment device, compares the measured pressure value with a preset value, and adjusts an opening of the control valve 12 according to a comparison result, that is, when the measured pressure value of the reaction chamber is more than the preset value, the opening of the control valve 12 is turned up to increase the amount of the gas to be pumped, thereby lowering the pressure in the reaction chamber; when the measured pressure value of the reaction chamber is less than the preset value, the opening of the control valve 12 is turned down to reduce the amount of gas to be pumped, thereby reducing the pressure in the reaction chamber.

At the low pressure of 1-20 Torr required by the disclosure, the chamber has a small amount of gas therein. Therefore, the accurate control of the pressure in the reaction chamber is important for the generation and oxidation reaction of oxygen radicals with a high quality a high efficiency.

The low-pressure oxidation treatment method according to the disclosure further includes introducing nitrogen gas into the reaction chamber before the semiconductor workpiece (e.g., wafer) to be treated enters the reaction chamber and after the low-pressure oxidation treatment reaction is completed.

The low-pressure oxidation treatment method according to the disclosure utilizes the low-pressure and high-temperature conditions to facilitate the generation of oxygen radicals from oxygen, and under the promotion of hydrogen, the oxygen radicals exhibit prolonged survival time and are easier to diffuse into a deep silicon layer, This, in turn, enables the attainment of a deeper oxidation extent, reduces the defects within the oxide film and yields a superior-quality oxide film suitable for diverse advanced processes.

It should be understood that various forms of the processes as shown above may be used for reordering, adding or omitting steps. For example, the steps described herein may be executed concurrently, sequentially or in different orders, and are not limited herein as long as the desired outcomes of the technical solutions disclosed in the disclosure can be achieved.

The above detailed description should not be construed as limiting the scope of the disclosure. It should be understood by those skilled in the art that various modifications, combinations, sub-combinations and substitutions may be made, depending on design requirements and other factors. Any modification, equivalent replacement, and improvement made within the principle of the present disclosure should be included in the protection scope of the present disclosure.

What is claimed is:

1. A low-pressure oxidation treatment method for a semiconductor workpiece, comprising:
pumping a reaction chamber such that the reaction chamber has a pressure lower than 760 Torr;
introducing a process gas including hydrogen and oxygen to the reaction chamber;
increasing a temperature within the reaction chamber to cause the process gas to generate oxygen radicals; and
exposing the semiconductor workpiece to the oxygen radicals to form an oxide film on a surface of the semiconductor workpiece.

2. The low-pressure oxidation treatment method of claim 1, wherein oxygen radicals are generated from the process gas at 750 to 1100° C.

3. The low-pressure oxidation treatment method of claim 1, wherein the low pressure is 1 to 20 Torr.

4. The low-pressure oxidation treatment method of claim 1, wherein a flow percentage of hydrogen is 33% or less and not zero, and a flow percentage of oxygen is 67% or more and not 100%, based on the total flow of the process gas.

5. The low-pressure oxidation treatment method of claim 1, wherein the hydrogen is supplied when a pressure in the reaction chamber is below 20 Torr.

6. The low-pressure oxidation treatment method of claim 1, wherein a total flow rate of the process gas is 20 to 60 L/min.

7. The low-pressure oxidation treatment method of claim 1, wherein the process gas is supplied from a side surface, a top surface, or both the side and top surfaces of the reaction chamber.

8. The low-pressure oxidation treatment method of claim 2, wherein the process gas is supplied from a side surface, a top surface, or both the side and top surfaces of the reaction chamber.

9. The low-pressure oxidation treatment method of claim 3, wherein the process gas is supplied from a side surface, a top surface, or both the side and top surfaces of the reaction chamber.

10. The low-pressure oxidation treatment method of claim 4, wherein the process gas is supplied from a side surface, a top surface, or both the side and top surfaces of the reaction chamber.

11. The low-pressure oxidation treatment method of claim 5, wherein the process gas is supplied from a side surface, a top surface, or both the side and top surfaces of the reaction chamber.

12. The low-pressure oxidation treatment method of claim 6, wherein the process gas is supplied from a side surface, a top surface, or both the side and top surfaces of the reaction chamber.

13. A low-pressure oxidation treatment device for a semiconductor workpiece, comprising a reaction chamber, at least one heating element, and a vacuum generating system.

14. The low-pressure oxidation treatment device of claim 13, wherein the vacuum generating system comprises a vacuum pump, a sensor, and a control valve.

15. The low-pressure oxidation treatment device of claim 13, further comprising at least one process gas inlet provided on a side wall at an end of the reaction chamber.
